(19) United States
(12) Patent Application Publication
(10) Pub. No.: US 2024/0227290 A1
(43) Pub. Date: Jul. 11, 2024

(54) HIGH-THROUGHPUT 3D-PRINTING

(71) Applicant: Danmarks Tekniske Universitet, Kongens Lyngby (DK)

(72) Inventors: Anja Boisen, Kongens Lyngby (DK); En-Te Hwu, Kongens Lyngby (DK); Tien-Jen Chang, Kongens Lyngby (DK)

(73) Assignee: Danmarks Tekniske Universitet, Kongens Lyngby (DK)

(21) Appl. No.: 18/279,457

(22) PCT Filed: Mar. 1, 2022
(86) PCT No.: PCT/DK2022/050033

§ 371 Date: Aug. 30, 2023

(30) Foreign Application Priority Data
Mar. 4, 2021 (EP) 21160737.9

(51) Int. Cl. B29C 64/241; B29C 64/129; B29C 64/245; B29C 64/268; B33Y 10/00; B33Y 30/00

(52) U.S. Cl. CPC B29C 64/241; B29C 64/129; B29C 64/245; B29C 64/268; B33Y 10/00; B33Y 30/00

(57) ABSTRACT

Disclosed is a method of 3D-printing a polymer-based structure comprising at least one polymer-based substructure. The method comprised the steps of depositing a photocurable resin onto a spinnable substrate, spin coating a layer comprising said photocurable resin on said spinnable substrate by spinning said spinnable substrate, and irradiating said layer, while spinning said spinnable substrate, at one or more selected positions with a light source to cure at least a portion of said layer, thereby forming a polymer-based substructure. A system for 3D-printing a polymer-based structure comprising at least one polymer-based substructure is further disclosed.

### FIELD OF THE INVENTION

The present invention relates to a method of and a system for 3D-printing a polymer-based structure comprising at least one polymer-based substructure.

### BACKGROUND OF THE INVENTION

Additive manufacturing, commonly referred to as 3D-printing, has been playing an ever-increasing role in manufacturing for the past two decades. 3D-printing enables fast prototyping without time-consuming subtractive manufacturing and revolutionizes the structural design concept of a system. From civil engineering and aerospace industry to the pharmaceutical fields, 3D-printing has changed how humans are making objects.

There exist several 3D-printing techniques such as selective laser sintering (SLD), material extrusion-based fused deposition modelling (FDM), digital light process (DLP), stereolitography (SLA), multi-jet fusion (MJF), electron beam melting (EBM) and two-photon polymerization (TPP).

Many 3D-printing techniques share a common drawback, namely a low throughput, which is a longstanding bottleneck to mass production. The DLP- and some SLA-based systems have a high throughput, but the printing resolution is limited to tens of micrometres. Most microscale and nanoscale 3D-printers solidify physical objects with a raster scanning method, in which printing coordinates are defined in a three-dimensional space with a cartesian coordinate (x, y, z) system. This raster scanning method requires a constant change of scanning direction of a printer head or a laser beam to cure a solid structure. Therefore, they need fast-moving mechanical actuators or fast rotating mirrors in order to print a 3D-object quickly and realize a high throughput. Such systems are typically also very expensive as they rely on the use of expensive components. This seriously hinders broad usage of such 3D-printing systems.

It is even more challenging to increase the throughput of microscale and nanoscale 3D-printing in a centimetre square scale area without using a stitching process.

Thus, there exists a need of methods and systems for printing structures/objects which combines a high printing resolution with a high throughput in a cost-effective way. It is therefore an object of the present invention to provide such a method and a system.

### SUMMARY OF THE INVENTION

The inventors have identified the above-mentioned problems and challenges related to 3D-printing of microscale and nanoscale objects with a high throughput, and subsequently made the below-described invention which may improve throughput of 3D printed structures on the microscale and/or nanoscale.

The invention relates to a method of 3D-printing a polymer-based structure comprising at least one polymer-based substructure, said method comprising the steps of:
(i) depositing a photocurable resin onto a spinnable substrate;
(ii) spin coating a layer comprising said photocurable resin on said spinnable substrate by spinning said spinnable substrate; and
(iii) irradiating said layer, while spinning said spinnable substrate, at one or more selected positions with a light source to cure at least a portion of said layer,
thereby forming a polymer-based substructure.

Thereby is achieved an advantageous way of 3D-printing a polymer-based structure which may achieve a high throughput of printing when printing microscale and nanoscale structures.

As opposed to typical 3D-printing methods based on the raster scanning method, the present method is based on spinning/rotating a spinnable substrate on which the printing occurs, and the polymer-based structure is build. By employing a spinning substrate, the linear printing speed is no longer limited by actuation of a printing head, but rather set by the rotational speed of the spinnable substrate. Instead of moving a print head in a raster-scanning fashion, which requires constant changes to the relative position of such a print head with respect to the substrate or stage on which the structure is printed, the print position on the spinnable substrate can be controlled through spinning of the spinnable substrate alone, and optionally, by a linear translation of the light source along a radial axis extending between from the center of rotation of the spinnable substrate and an edge of the spinnable substrate.

The linear speed of a point on the spinnable substrate is given by the product of the angular speed of the spinnable substrate and the radial distance between the center of rotation of the spinnable substrate and the point on the spinnable substrate. Thus, for a given rotational/angular speed the linear speed of a point on the spinnable substrate increases proportionally with the distance between the point and the center of rotation. Furthermore, the linear speed is proportional to the angular speed, and therefore increasing the angular speed of the spinnable substrate results in a proportional increase in the linear speed of a point on the spinnable substrate.

It is therefore advantageous to utilize a spinning method according to the present method, as there no longer is a requirement of fast-moving actuators to achieve a high linear printing speed, and the realizable linear printing speeds may be orders of magnitude greater than the linear printing speeds realizable by conventional methods employing the raster scanning method. In principle, increasing the linear printing speed with the present method only requires spinning the spinnable substrate at a greater angular speed, which may simply be realized by spinning a motor at a greater speed. In embodiments of the invention, the linear printing speed may be at least 500 mm per second, or even at least 1000 mm per second.

The present method advantageously combines a spinnable substrate with a method of printing that is well suited to print using such a substrate. The method includes a step of depositing a photocurable resin onto the spinnable substrate. Such a resin has at least two properties that makes it advantageous for the present 3D-printing method:
a) The photocurable resin may solidify when subjected to light. Thus, by irradiating light onto selected portions of a layer of comprising the photocurable resin, selected portions of the layer may be solidified, and printing is realized. Light irradiation may typically be controlled on timescales that are several orders of magnitude smaller than the timescales typically involved in movement of mechanical actuators.
b) The photocurable resin is well suited for spin coating. Thus, by depositing the photocurable resin on the spinnable substrate and spinning the substrate, a layer comprising photocurable resin may be made on top of the spinnable substrate. The thickness of this layer may be adjusted through e.g., adjusting properties of the photocurable resin, such as its viscosity, and/or the amount of photocurable resin, however, the thickness of the layer may also be adjusted by changing the angular speed of the spinnable substrate.

In summary, the present method of 3D-printing a polymer-based structure is advantageous for the following reasons.
The method combines a spinnable substrate with a printing technique based upon irradiating a photocurable resin with light from a light source. Since the substrate may spin at high angular speeds, leading to high linear speeds of points on/in the layer of the layer comprising the photocurable resin, and since irradiation with light may be controlled at great precisions (a suitable light source may be turned on and off very quickly) a high throughput may be achieved even for printing of very small polymer-based structures, such as structures on the nanoscale and/microscale.
The method is based on irradiating a layer comprising photocurable resin at selected positions. Since the irradiation is done using a light source the positions on the spinning layer of photocurable resin may be selected very precisely by timely control of the irradiation. In this manner, high printing precision may be achieved.
The method is further advantageous in that it combines spin coating with printing on a spinnable substrate. Because the printing employs a spinnable substrate, the very same substrate may also be used for spin coating the layer comprising photocurable resin. This simplifies the method, as all the steps of the method can be performed by the same 3D-printing system, and furthermore, additional layers of photocurable resin may be spin coated on top of already existing layers in which printing has occurred. Spin coating is furthermore a very useful method for producing layers of uniform thickness, and the thickness of layers can easily be controlled by spinning the spinnable substrate. Therefore, a 3D-printing system that implements the method of the present invention may also be able to fine tune the thickness of the layer, and at thicknesses on the nanometre scale. In this way a high precision of 3D-printing may be achieved in a direction perpendicular to the plane in which the spinnable substrate is positioned.

In the context of the present invention, the at least one polymer-based substructure comprises the polymer-based substructure formed by the steps (i)-(iii). In embodiments of the invention where the polymer-based structure comprises only one substructure, this substructure constitutes the polymer-based structure. In other embodiments of the invention where the polymer-based structure comprises two or more substructures, each substructure of the two or more substructures are formed by the steps (i)-(iii), and the two or more substructures constitutes the polymer-based structure.

In the context of the present invention, a “photocurable resin” is understood as a substance which changes its properties when exposed to light, such as light in the ultraviolet or visible region of the electromagnetic spectrum. These changes are often manifested structurally such as by hardening of the substance. A typical photocurable resin comprises photopolymers which may harden as a result of cross-linking of the photopolymers. The hardening property of photocurable resins makes such substances particularly advantageous for additive manufacturing, such as 3D-printing, as the printing process can effectively be light-controllable. By irradiating light at targeted portions of a photocurable resin, a desired polymer-based structure may be formed through hardening at these specific portions. Modern techniques have provided highly advanced and precise ways of manipulating with light, and therefore, light-controlled 3D-printing may achieve high precision due to the possibility of high precision control of the irradiation of the photocurable resin. The photocurable resin chosen for specific tasks is selected with consideration for parameters such as the wavelength and power of the laser, the spot size established by the optical system etc.

In the context of the present invention, “depositing” should be understood as the act of transferring a photocurable resin onto the spinnable substrate. The act of depositing/transferring the photocurable resin may include preparing the photocurable resin, such as diluting the photocurable resin to a desired concentration and controlling the amount of photocurable resin to be deposited.

In the context of the present invention, “spin coating” should be understood as the process of forming a thin film on top of the spinnable substrate by spinning/rotating the substrate at high rotational speeds. The act of spinning the spinnable substrate onto which the photocurable resin is deposited/transferred ensures that the photocurable resin is subjected to centrifugal forces which spreads the photocurable over the spinnable substrate to form a layer of the photocurable resin. In other words, a coating of the photocurable resin is formed on top of the spinnable substrate. Spin coating techniques are known for their abilities to provide thin layers having a very uniform thickness across the layer. Owing to self-levelling, thicknesses usually do not vary more than 1%. This makes spin coating a highly advantageous for the photocuring process of the present method, since precise coating of the spinnable substrate may result in end products, i.e., a photopolymer (sub)structure, that are made with a high precision.

In the context of the present invention, a “spinnable substrate” should be understood as any kind of substrate for supporting a layer of material, such as a layer of photocurable resin, and which is arranged is arranged to be rotated about an axis of rotation for forming such a layer of material by a spin coating process. In a preferred embodiment of the invention, the spinnable substrate is symmetric around the axis in which it is rotated. Such a spinnable substrate may be formed in the shape of a disc which is highly stable under spinning.

In the context of the present invention, “irradiating” should be understood as subjecting the photocurable resin, on the spinnable substrate, to illumination by light from a light source. The irradiation/illumination may be direct or indirect. That is, the light incident of the photocurable resin may emanate directly from the light source or it may have passed through one or more optical elements, such as lenses, before reaching the photocurable resin. In the context of the present invention, a “light source” should be understood as any kind of light source which is powered by electricity, such as a laser diode.

In the context of the present invention, “selected positions” should be understood as positions on or in the layer comprising the photocurable resin. The positions may be selected on the basis of a representation, such as a computer implemented representation, of the desired polymer-based structure which is desired to be printed using the steps of the present method.

In an embodiment of the invention, said photocurable resin comprises photopolymers. The photocurable resin may primarily comprise photopolymers, that are able to cross-link when exposed to light. This leads to a hardening of the photocurable resin. According to the specific requirements of the 3D-printing process the photocurable resin may also be diluted, with a less viscous solution, such as acrylate, methacrylate, n-hexane etc., to achieve a specific concentration of photopolymers. Dilution of the photocurable resin may affect the spin coating properties of the resin, and in some instances a dilution may be necessary to achieve a satisfactory spin-coated layer of the resin.

In an embodiment of the invention, said photocurable resin is a photopolymer.

In an embodiment of the invention, said photocurable resin comprises functionalized oligomers, such as epoxides, urethanes, polyethers or polyesters functionalized by an acrylate, for example acrylated epoxy oligomers.

It must be understood that suitable photocurable resins are not limited to the above list of photocurable resins, and indeed other photocurable resins may be usable for the purpose of carrying out the method of the present invention.

In an embodiment of the invention said photocurable resin comprises any of phthalates, methyl methacrylate, acrylic acid, and acrylate compounds.

In an embodiment of the invention, a dynamic viscosity of said photocurable resin is in the range from 30 cP to 10000 cP at a temperature of 30 degrees celsius. For sake of completeness, it should be noted that “cP” is an abbreviation of the unit “centipoise”, which is a measure of dynamic viscosity. Dynamic viscosity (also known as absolute viscosity) is a property relating to a fluid's internal resistance to flow.

A skilled person would know how to achieve a prescribed dynamic viscosity of the photocurable resin within the range from 30 cP to 10000 cP at a temperature of 30 degrees celsius. For example, the dynamic viscosity may be adjusted by using viscosity enhancing means capable of increasing the effective viscosity of the photocurable resin, such as a viscosity enhancing agent selected from ethylene propylene diene monomer (EPDM), oxidized polyethylene (OPE), dextran, polyvinylpyrrolidone (PVP), and Polyethylene glycol (PEG). Oppositely, the effective dynamic viscosity may be reduced by use of viscosity decreasing means such as diluting solvents selected from isopropyl alcohol (IPA), tetrahydrofuran (THF), ethylenediamine (ED), and dimethylformamide (DMF). Furthermore, the viscosity of a polymer is affected by water salinity and divalent ions such as calcium and magnesium, which decrease the viscosity of the polymer solution.

It should be noted that a reference to a dynamic viscosity of a photocurable resin may also refer to an effective dynamic viscosity of a solution/mixture comprising the photocurable resin. For example, the dynamic viscosity may refer to the effective dynamic viscosity of a mixture of a photocurable resin and a viscosity enhancing agent or the effective dynamic viscosity of a mixture of a photocurable resin and a solvent.

The skilled person would know that the dynamic viscosity may also be adjusted by e.g., change of temperature.

By selection of the dynamic viscosity it may be possible to adjust a thickness of a spin-coated layer for a given rotational speed (i.e. spin coating rotational speed) during the step of spin coating. The skilled person is aware of the implications of both viscosity and spin coating rotational speeds on the spin coating process and will readily appreciate that a photocurable resins of low viscosity are not suitable for high rotational speeds. If the viscosity is low, such as below 30 cP the photocurable resin may easily be ejected from the spinnable substrate during high rotational speeds due to centrifugal forces. Increasing the viscosity of a photocurable resin may result in a better resolution in thickness of a spin coated layer. This can be illustrated by an example. Take two different photocurable resins; A and B. Both photocurable resins can be used to produce a 10 micrometre thick spin-coated layer at respectively 1000 rpm and 100 rpm. If a thickness of 0.1 micrometre is desired, the photocurable resin A would have to be spun at 10 rpm whereas photocurable resin B would have to be spun at 1 rpm. The 1 rpm spin coating would be very unstable in the homogeneity of the spin-coated layer.

In an embodiment of the invention, said step of irradiating said layer, when said spinnable substrate is spinning, comprises translating said light source in a plane parallel to a plane in which said spinnable substrate is positioned when said spinnable substrate is stationary. Translating the light source in a parallel plane to the plane in which the spinnable substrate is positioned is advantageous in that it may be possible for the light source to irradiate extended portions of the spinnable substrate, such as an entire spin coated layer of photocurable resin. In a further embodiment of the invention, said translating said light source comprises translating said light source along a radial axis, said radial axis extending between a center of rotation of said spinnable substrate and an edge of said spinnable substrate. Translating the light source along a radial axis extending between the center of rotation/spinning of the spinnable substrate and an edge of the spinnable substrate is advantageous in that an extended portion of the spinnable substrate may be irradiated as the spinnable substrate is spinning/rotating around its center of rotation/spinning. This is particularly advantageous if the spinnable substrate is a disc-shaped spinnable substrate. In an embodiment of the invention, said translating said light source consists of translating said light source along a radial axis, said radial axis extending between a center of rotation of said spinnable substrate and an edge of said spinnable substrate. In this embodiment of the invention, the translation of the light source, in the plane parallel to the plane in which the spinnable substrate is positioned, is thus restricted to only a linear translation along the radial axis.

In an embodiment of the invention, said light source is any source of light that is capable of curing a photocurable resin, such as a continuous wave laser, a pulsed laser, or a two-photon laser. A skilled person would appreciate that the choice of light source impacts the suitable choices of photocurable resins and likewise a selection of a photocurable resin impacts the suitable choices of light sources, as the power delivered by the light source should be able to be absorbed in the photocurable resin for curing thereof.

In an embodiment of the invention, said light source forms part of an optical pickup unit, such as a first optical pickup unit. The optical pickup unit may be an optical pickup unit suitable for a CD-ROM drive, DVD drive, HD-DVD drive or a Blu-Ray drive. Such optical pickup units comprise light sources, such as lasers, that are able to emit laser light which may solidify a photocurable resin.

According to an embodiment of the invention said step of irradiating comprises irradiating said layer with light having a spot size of between 100 nm and 1500 nm. The spot size may be defined as an area of intersection of light from the light source(s) on the spinnable substrate. The smaller the spot size the higher resolution may be achieved in the 3D-printing.

According to an embodiment of the invention said light source is a first light source and wherein said step of irradiating comprises irradiating at one or more selected positions with one or more further light sources including at least a second light source.

The photocurable resin may be subject to lighting from a plurality of light sources, i.e., further light sources in addition to the previously mentioned light source. This is advantageous in that for example the printing throughput may be improved, in particular when polymer-based structures are printed on a small length scale. With the presence of a single light source the speed of the 3D printing may be limited by the switching of the light source, however, with multiple light sources printing on different radial positions of the same spinnable substrate, the throughput can be doubled, tripled, etc. it may be possible to improve the overall duty cycle of the 3D-printing (i.e., the total time in which the spinnable substrate is subject to lighting for curing the photocurable resin increases). In addition to switching, the printing throughput can also be limited by viscosity and sensitivity of the photocurable resin.

According to an embodiment of the invention, said step of depositing comprises depositing said photocurable resin onto said spinnable substrate while spinning said spinnable substrate. During this step the spinnable substrate may spin at a first rotational speed, which may also be referred to as a deposition rotational speed.

The photocurable resin may be deposited onto the spinnable substrate while it is spinning around. In this way, the photocurable resin may be uniformly or symmetrically deposited around a centre of rotation/spinning of the spinnable substrate. Depositing the photocurable resin onto the spinnable substrate while the spinnable substrate is spinning is advantageous in that the photocurable resin may be deposited uniformly/symmetrical about the axis of rotation which ensures that a uniform layer of photocurable resin may be spin coated. This is particularly advantageous if, for reasons of system-related limitations, the photocurable resin may not be deposited on top of the spinnable substrate at the centre of rotation/spinning but have to be deposited at an offset from this centre. If the photocurable resin is deposited off-centre and the spinnable substrate is spinning/rotating in the meanwhile, the photocurable resin is deposited on a donut formed shape around the centre of rotation. This may be the case if the spinnable substrate comprises, for example, attachment mechanism at its center of rotation, the attachment mechanism enabling the spinnable substrate to be attached to a driving system for spinning the spinnable substrate. Once the spinnable substrate is rotated at greater rotational speeds, centrifugal forces will spread the photocurable resin outwards from the centre of rotation and away from the initial donut-shaped deposit of photocurable resin. Thereby is achieved a uniform layer of photocurable resin on the spinnable substrate in the region extending from the initial donut-shaped deposit and outwards to an outer edge of the spinnable substrate. In this way most of the usable upper surface of the spinnable substrate may be spin coated with a uniform layer of photocurable resin.

According to an embodiment of the invention, said step of depositing comprises depositing said photocurable resin in a predetermined amount.

By depositing a predetermined amount of photocurable resin onto the spinnable substrate 2 it becomes possible to perform stable feed of the photocurable resin in a minimum required amount in order to prevent variation in thickness of the subsequent spin coated layer 3 of photocurable resin.

In an embodiment of the invention, said predetermined amount of photocurable resin is deposited within a predetermined time period.

In an embodiment of the invention, said step of depositing said photocurable resin onto said spinnable substrate is performed by use of a dispenser, such as by use of an automatic dispenser.

According to an embodiment of the invention, said spinnable substrate is a disc-shaped spinnable substrate. A disc-shaped substrate is advantageous in that a disc shape has a low moment of inertia and a rotational symmetry, which renders the disc shape an ideal shape for spinning.

According to an embodiment of the invention, said spinnable substrate is a disc-shaped spinnable substrate comprising a center portion and a peripheral portion disposed around said center portion, and wherein said step of depositing comprises depositing said photocurable resin onto said peripheral portion of said disc-shaped spinnable substrate.

According to an embodiment of the invention, said disc-shaped spinnable substrate has a diameter in the range from 5 mm to 300 mm.

The disc-shaped spinnable substrate may have a diameter, in the plane of rotation, which is in the range from 5 mm to 300 mm. Too large diameters, i.e., diameters exceeding 300 mm may result in large amplitudes of disc wobble which may be difficult to compensate for. Too small diameters of the disc-shaped spinnable substrate, i.e., diameters of less than 5 mm, may entail disc wobble that is difficult to detect.

In an embodiment of the invention, said spinnable substrate is a disc-shaped spinnable substrate which is arranged to engage and fixate to a driving system, such as a driving system for a CD-drive, a DVD-drive, an HD-DVD-drive or a Blu-Ray-drive. The disc-shaped substrate may for example be a CD, DVD, HD-DVD, or a Blu-Ray disc. Such types of discs typically comprise a hole in its center where the disc may engage and fixate to a driving system for spinning the disc. In such a case, it is advantageous to not deposit the photocurable resin directly at the centre portion of the disc (the centre of rotation) as this part is an aperture where the disc/substrate does not exist. Thus, depositing the photocurable resin off-centre, i.e., on the peripheral portion of the disc ensures that only solid parts of the spinnable substrate/disc is spin coated with the photocurable resin.

According to an embodiment of the invention, said layer comprising said photocurable resin has a thickness of up to 100 micrometres.

The layer comprising the photocurable resin may have a thickness of up to 100 micrometres, e.g., a thickness in the range from 0 to 100 micrometres, such as a thickness in the range from 100 nanometres to 100 micrometres, such as in the range from 100 nanometres to 50 micrometres, such as in the range from 200 nanometres to 20 micrometres, such as 500 nanometres to 10 micrometres, such as in the range from 1 to 3 micrometres, for example 2 micrometres.

In an embodiment of the invention, the thickness of the layer is at the one or more selected positions. In another embodiment of the invention, the thickness is a maximum thickness of the layer.

The thickness dimensions may also refer to a thickness of each layer of a polymer-based structure comprising multiple 3D-printed layers. This does not however, imply that each layer has the same thickness but that the limits of layer thickness apply to each layer.

According to an embodiment of the invention said polymer-based structure has a height of up to 10 millimetres.

By height is referred to a height in a direction perpendicular to the spinnable substrate. The polymer-based structure may have a thickness of up to 10 millimetres, such as a height in the range between 100 nanometres and 10 millimetres, such as a height in the range from 1 micrometre to 10 millimetres, such as from 10 micrometres to 1 millimetre, for example 100 micrometres.

According to an embodiment of the invention, said step of irradiating said layer, while spinning said spinnable substrate, comprises dynamically adjusting a position of said light source with respect to an equilibrium position.

Most physical objects, that are spinning around an axis of rotation which passes through the object, will display a certain level of wobbling due to uneven, and non-perfect, mass distribution. For example, the edges of a non-perfect spinning disc may deflect away from an equilibrium state of the disc, when the disc is not spinning. Such deflections may be in a direction perpendicular direction to the plane in which the disc is positioned when stationary. The deflections, which occur over time as the disc is spinning are referred to dynamical movements of the disc, or simply referred to as disc wobble.

In a similar manner, the spinnable substrate of the present invention may wobble as it rotates around its axis of rotation. In situations where the spinnable substrate wobbles it is advantageous to compensate for this wobbling.

According to an embodiment of the invention said step of irradiating said layer, while spinning said spinnable substrate, comprises dynamically adjusting a point of interaction of light of said light source with said spinnable substrate.

By dynamically adjusting is understood that the light output from the light source is dynamically adjusted, i.e., adjusted in real time, in such a way that a desired point of interaction of the light with the spinnable substrate is adjusted in real time to follow changes in vertical position of the spinnable substrate, and thereby ensuring that the light interacts with the spinnable substrate at the desired positions. In other words, light produced by the light source may dynamically track displacements of the spinnable substrate and thereby is achieved an advantageous way of compensation of such wobbling, and it enables for an improved precision in the 3D-printing.

Dynamic adjusting a point of interaction of light with said spinnable substrate with respect to an equilibrium position may be achieved through e.g., dynamically changing a vertical position of focus of said light source.

This may be done by dynamically adjusting a position of the light source with respect to the spinnable substrate which has the effect that the position of the light source is also dynamically adjusted with respect to a layer comprising the photocurable resin on top of the spinnable substrate.

By dynamically adjusting a position of the light source may be understood that a distance between the light source and the spinnable substrate is maintained as the spinnable substrate is rotated. For example, the light source may be fixed in a lateral plane over the spinnable substrate, the lateral plane being parallel to the plane in which the spinnable substrate is positioned when it is stationary, and as the spinnable substrate is rotated it may move upwards towards the light source. By dynamically adjusting a position of the light source, the position in the lateral plane is maintained, however the position of the light source along an axis perpendicular to the lateral plane may is changed, as the disc is rotated, in such a way that the distance between the light source and the spinnable substrate along the axis is maintained.

Dynamically adjusting adjusting a point of interaction of light from said light source with said spinnable substrate may for example be done by use of optical means such as optical mirrors and lenses. For example, the point of interaction of the light source and the spinnable substrate may be dynamically adjusted through adjustments of focus using lenses. Dynamically adjusting a point of interaction of said light source with said spinnable substrate is advantageous in that a greater precision in 3D-printing may be achieved.

Dynamically adjusting a position of said light source with respect to said spinnable substrate is advantageous in that a greater precision in the 3D-printing may be achieved.

According to an embodiment of the invention, said dynamically adjusting comprises detecting movements of said spinnable substrate along an axis perpendicular to a plane in which said spinnable substrate is positioned and adjusting said position of said light source along said axis on the basis of said detected movements.

According to an embodiment of the invention, said movements of said spinnable substrate are detected by use of a detection unit.

In an embodiment of the invention, said detection unit is an optical sensor.

According to an embodiment of the invention, said optical sensor is arranged to detect movements of said spinnable substrate by use of an astigmatic detection method, a beam deflection method, interferometry, or capacitance-based distance sensing.

In an embodiment of the invention, said optical sensor is an optical pickup unit, such as a second optical pickup unit.

According to an embodiment of the invention, said step of irradiating said layer comprises sequentially turning on and off said light source.

As the spinnable substrate is spinning/rotating around, and only selected portions of the layer comprising the photocurable resin are to be irradiated with light from the light source, it may be necessary, depending on the polymer-based structure intended to be 3D-printed, to turn on and off the light source at specific times such that the light source only irradiates the layer at specific times and for specific durations. For this reason, it is advantageous to sequentially turning on and off the light source.

According to an embodiment of the invention, said step of spin coating comprises spinning said spinnable substrate at a second rotational speed and said step of irradiating said layer comprises spinning said spinnable substrate at a third rotational speed, wherein said second rotational speed is equal to or greater than said third rotational speed. The second rotational speed may also be referred to as a spin coating rotational speed. The third rotational speed may also be referred to as a print rotational speed.

The spinnable substrate may spin/rotate at various rotational speeds. In the first step of the method in which the photocurable resin is deposited onto the spinnable substrate the substrate may be stationary/non-rotating or it may rotate at a first rotational speed. In an embodiment of the invention, the first rotational speed is in the range from 20 rpm to 200 rpm (rpm=rotations per minute), such as in the range from 40 rpm to 160 rpm, such as in the range from 60 rpm to 120 rpm. The spinnable substrate may rotate at a second rotational speed during the second step of the method which comprises spin coating a layer comprising the photocurable resin. In an embodiment of the invention, said second rotational speed is in the range from 300 rpm to 10000 rpm, such as from 300 rpm to 6000 rpm. The spinnable substrate may rotate at a third rotational speed during the third step of the method which comprises irradiating the layer comprising the photocurable resin. In an embodiment of the invention, said third rotational speed is in the range from 120 rpm to 5900 rpm. In an embodiment of the invention, said second rotational speed is greater than said first rotational speed.

According to an embodiment of the invention, said method comprises a further step (iv) of repeating said steps (i)-(iii) one or more further times, thereby forming one or more further polymer-based substructures.

In an embodiment of the invention, said light source is arranged to irradiate light at a wavelength in the range from 100 nanometres to 2000 nanometres, such as from 100 nanometres to 1000 nanometres. The light used for irradiation may have a wavelength in the range from 100 nanometres to 2000 nanometres, such as from 100 nanometres to 1000 nanometres, such as in the range from 200 nanometres to 800 nanometres, such as in the range from 400 nanometres to 800 nanometres, for example selected from the wavelengths of 405 nanometres, 650 nanometres or 780 nanometres.

In an embodiment of the invention, said method comprises a further step of washing said spinnable substrate to remove residues of photocurable resin. In an embodiment of the invention, said spinnable substrate is washed using a solution comprising an alcohol, for example ethanol. In an example, the spinnable substrate is washed using a solution comprising isopropyl alcohol (IPA) or 75 weight percent of ethanol.

In an embodiment of the present invention, one or more of the steps of the method, such as all the steps of the method, are carried out by means of a computer processor. In this way, the method of the present invention may be an automated process of 3D-printing.

In an embodiment of the invention, a combination of different types of photocurable resins may be applied. For example, different photocurable resins may be applied in different layers to obtain polymer-based structures comprising different materials in different regions or layers.

In an embodiment of the invention, the method is adapted to be carried out using the system for 3D-printing a polymer-based structure according to the invention or any of its embodiments.

According to an alternative embodiment of the invention, disc wobble may be reduced using an air bearing facilitating a low-friction and balancing interface with the spinnable substrate. The disc wobble may be reduced by compensating the disc wobble using the air bearing.

The invention further relates to a system for 3D-printing a polymer-based structure comprising at least one polymer-based substructure, said system comprising:
a dispenser configured to deposit a photocurable resin onto a spinnable substrate; and
a driving system for receiving said spinnable substrate thereto, said driving system comprising a motor configured to spin said spinnable substrate to at least form a layer comprising said photocurable resin;
a controller; and
a light source configured to irradiate and cure said photocurable resin deposited onto said spinnable substrate, wherein said light source is configured to emit light in response to a control signal provided by said controller, and wherein said system is configured to dynamically adjust a point of interaction of said light source with said spinnable substrate.

In an embodiment of the invention, said system is configured to dynamically adjust said point of interaction of said light source with said spinnable substrate by maintaining a relative distance between said light source and said spinnable substrate.

In an embodiment of the invention, said system comprises said spinnable substrate.

In an embodiment of the invention, said dispenser is an automatic dispenser.

In an embodiment, the dispenser is arranged to receive a control signal from the controller and dispense an amount of photocurable resin according to said received control signal.

In an embodiment of the invention, the controller is configured to transmit control signal to the dispenser and the driving system to adjust the amount of photocurable resin dispensed from the dispenser and the angular speed of the spinnable substrate to obtain a thickness of photocurable resin spin coated on the substrate to a predefined thickness. The predefined thickness may be in accordance with an externally received input, e.g. from an operator of the system.

In an embodiment of the invention, said system comprises a vertical displacement unit configured to adjust a vertical position of said light source. The vertical displacement may be in a communicative connection with the controller, such that it is responsive to control signals provided by the controller.

In an embodiment of the invention, said driving system is in communicative connection with said controller. In this way the controller may control the driving system, such as controlling the rotational speed of the motor and thus the rotational speed of the spinnable substrate.

In an embodiment of the invention, said spinnable substrate is a disc-shaped spinnable substrate.

In an embodiment of the invention, said spinnable substrate is removably fixated to said driving system. In this way the spinnable substrate may be replaced and/or removed from the system for post-printing procedures, such as washing of the spinnable substrate.

In an embodiment of the invention, said system comprises a container for receiving photocurable resin that is ejected from the spinnable substrate as a layer of photocurable resin is spin coated onto the spinnable substrate. When spin coating it is common that some of the substance used for forming the layer is ejected from the substrate/stage where the spin coated layer is formed. Having a container is advantageous in that it becomes possible for the system to collect excess photocurable resin and re-use this for a new spin coated layer comprising photocurable resin.

In an embodiment of the invention, said light source is arranged to irradiate light at wavelength in the range from 100 nanometres to 2000 nanometres, such as from 100 nanometres to 1000 nanometres. The light used for irradiation may have a wavelength in the range from 100 nanometres to 2000 nanometres, such as 100 nanometres to 1000 nanometres, such as in the range from 200 nanometres to 800 nanometres, such as in the range from 400 nanometres to 800 nanometres, for example selected from the wavelengths of 405 nanometres, 650 nanometres or 780 nanometres.

In an embodiment of the invention said light source is arranged to emit light with a power of 0.1 microwatts to 3000 microwatts, such as from 100 microwatts to 3000 milliwatts, such as 200 microwatts to 1000 milliwatts, such as 300 microwatts to 100 milliwatts. For example, the light source may be arranged to emit light with a power of about 400 microwatts, about 600 microwatts, about 1 milliwatt, about 0.1 milliwatt or about 10 milliwatts.

In an embodiment of the invention, said system comprises a detection unit.

In an embodiment of the invention, said detection unit is an optical sensor.

In an embodiment of the invention said light source comprises a laser.

In an embodiment of the invention said light source is arranged adjacent to a first side of said spinnable substrate, and wherein said system further comprises a detection unit arranged on a second side of said spinnable substrate, said first side and second side being opposite sides of said spinnable substrate, wherein said detection unit is arranged to detect movements of said spinnable substrate along an axis perpendicular to a plane in which said spinnable substrate is positioned.

In an embodiment of the invention, said system comprises a first radial displacement unit for translating said light source along a radial axis parallel to a first side of said spinnable substrate, and a second radial displacement unit for translating said detection unit along said radial axis. The first and second radial displacement units may be in a communicative connection with the controller, such that they are responsive to control signals provided by the controller.

In an embodiment of the invention, said light source is a first light source, and wherein said system comprises one or more further light sources including a second light source, said one or more further light sources being configured to irradiate and cure said photocurable resin deposited onto said spinnable substrate, wherein said one or more further light sources are configured to emit light in response to a control signal provided by said controller.

In an embodiment of the invention, the system according to any of the above-described embodiment are configured to carry out any of the steps of a method according to the invention or any of its embodiments.

As the system is arranged to carry out any of the steps of a method according to embodiments of the present invention, the system has the same advantages as these methods.

### THE DRAWINGS

Various embodiments of the invention will in the following be described with reference to the drawings, where

FIGS. 1a-1d illustrates steps of a method of 3D-printing a polymer-based structure comprising at least one polymer-based substructure according to embodiments of the present invention,

FIGS. 2a-2d illustrates polymer-based structures and polymer-based substructures which are 3D-printed using methods according to embodiments of the present invention,

FIGS. 3a-3d illustrates steps of depositing a photocurable resin onto a spinnable substrate and spin coating a layer of the photocurable resin on the spinnable substrate according to embodiments of the present invention,

FIGS. 4a-4c illustrates a system for 3D-printing a polymer-based structure comprising at least one polymer-based substructure according to an embodiment of the invention,

FIGS. 5a-5b illustrates sideview of a system for 3D-printing a polymer-based structure comprising at least one polymer-based substructure according to an embodiment of the invention,

FIGS. 6a-6b illustrates sideview of a system for 3D-printing a polymer-based structure comprising at least one polymer-based substructure according to another embodiment of the invention,

FIGS. 7a-7b illustrates actual SEM-images of polymer-based structures made using methods and systems according to the present invention,

FIGS. 8a-8b illustrates actual SEM-images of polymer-based structures made using methods and systems according to the present invention,

FIGS. 9a-9b illustrates among others a 1951 USAF resolution test chart and a corresponding SEM-image of polymer-based structures made using methods and systems according to the present invention,

FIGS. 10a-10g illustrates among others actual SEM-images of polymer-based structures made using methods and systems according to the present invention, and

FIG. 11 illustrates another polymer-based structure comprising three printed layers made using methods and systems according to the present invention.

### DETAILED DESCRIPTION

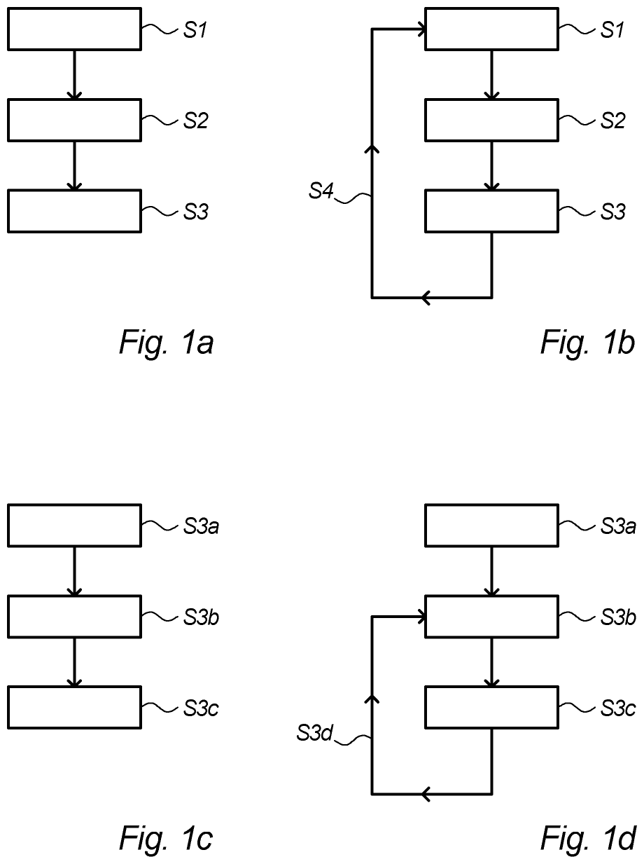

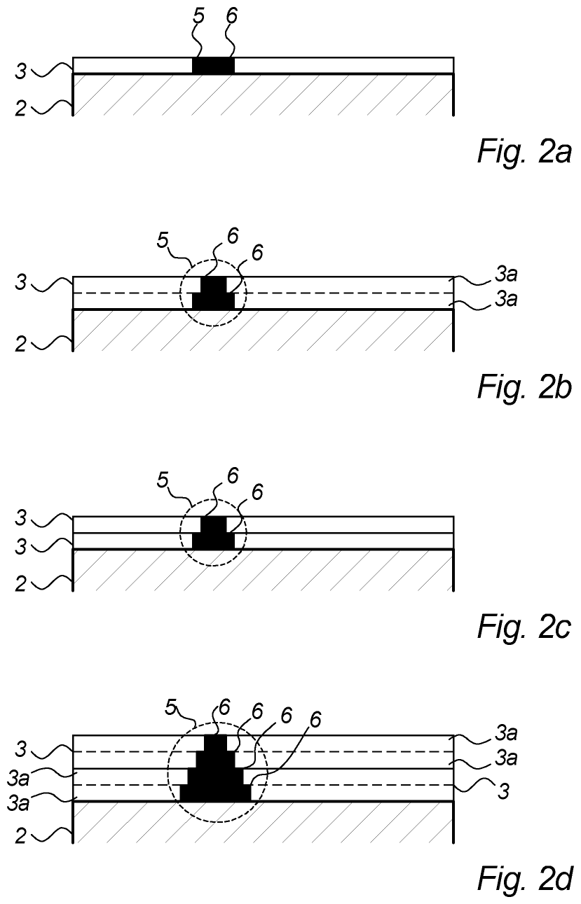

FIG. 1a shows steps S1-S3 of a method of 3D-printing a polymer-based structure 5 comprising at least one polymer-based substructure 6 according to an embodiment of the present invention. In a first step S1 a photocurable resin 1 is deposited onto a spinnable substrate 2. In a second step S2 the spinnable substrate 2 is spun in such a way that a layer 3 comprising the photocurable resin 1 is spin coated on the spinnable substrate 2. In a third step S3, the layer 3 comprising the photocurable resin 1 is irradiated, while the spinnable substrate 2 is spinning, at one or more selected positions with a light source 4 to cure at least a portion of the layer 3. In this way, a polymer-based substructure 6 is formed. An example of such a polymer-based structure 5 is shown in FIG. 2a.

FIG. 1b shows steps S1-S4 of a method of 3D-printing a polymer-based structure 5 comprising at least one polymer-based substructure 6 according to another embodiment of the invention. The steps S1-S3 are identical to the steps S1-S3 as shown in FIG. 1a, however a fourth step S4 included in this method. The fourth step S4 comprises repeating the steps S1-S3 any number of times, such that all in all, the set of steps S1-S3 are performed a plurality of times, such as two or more times. The result of this is that two or more layers 3 of photocurable resin 1 are layered on top of each other, and several layers of photocurable resin 1 may be used in the printing process. In this way a polymer-based structure 5 having a height extending beyond a thickness of a single layer 3 of photocurable resin 1 may be 3D-printed. An example of such a polymer-based structure 5 is shown in FIG. 2b.

FIG. 1c shows embodiments of the invention where either the third step S3, as shown in relation with FIG. 1a, or the third step S3, as shown in relation with FIG. 1b, comprises additional sub-steps S3a-S3c. In the first sub-step S3a the layer 3 comprising the photocurable resin 1 is irradiated, while the spinnable substrate 2 is spinning, at one or more selected positions with a light source 4 to cure at least a portion of the layer 3. In the second sub-step S3b, a relative distance between the spinnable substrate 2 and light source 4 is changed, either by movement of the spinnable substrate 2, by movement of the light source 4, or by a combined movement of the spinnable substrate 2 and the light source 4. In a third sub-step S3c, the layer 3 comprising the photocurable resin 1 is irradiated again, while the spinnable substrate 2 is spinning, at one or more selected positions with a light source 4 to cure at least a portion of the layer 3. In this way two sublayers 3a of the layer 3 may be printed. This may be useful in that it becomes possible to 3D-print a multilayered polymer-based structure 5, each layer representing a polymer-based substructure 6, within the thickness of a single spin coated layer 3 of photocurable resin 1. Examples of such polymer-based structures 5 are shown in FIGS. 2c-2d.

FIG. 1d shows a variation of the embodiments of the invention as described in relation to FIG. 1c, in which the third step S3 comprises four sub-steps S3a-S3d. The sub-steps S3a-S3c are identical to the sub-steps S3a-S3c as shown in FIG. 1c, however a fourth sub-step S3d is included in this method. The fourth sub-step S3d comprises repeating sub-steps S3b and S3c any number of times, such that all in all, a first sub-step S3a is performed followed by performing the set of sub-steps S3b and S3c a plurality of times, such as two or more times. The result of this is that three or more sublayers 3a, for example several sublayers 3a, may be printed within the same spin-coated layer 3 of photocurable resin 1.

A skilled reader will appreciate that the method as shown in FIG. 1a may be performed such that once the steps S1-S3 are completed, a single layer 3 of photocurable resin 1 is spin coated on the spinnable substrate 2 and the 3D-printing occurs only at one height within this layer. In this case, the polymer-based substructure 6 formed by the 3D-printing constitutes the polymer-based structure 5. However, as shown in FIGS. 1c and 1d, the step S3 of irradiating may include irradiating two or more sub-layers 3a within a single layer 3 comprising the photocurable resin 1. In this case the polymer-based structure 5 comprises two or more polymer-based substructures 6 each of which is contained within a sub-layer 3a of the spin coated layer 3.

The skilled reader will equally appreciate that the method as shown in FIG. 1b may be performed such that once the steps S1-S4 are completed, two or more layers 3 of photocurable resin 1 are spin coated and the layers 3 are arranged on top of each other on the spinnable substrate 2. In the same manner as described above, the third step S3 shown in FIG. 1b may include sub-steps S3a-S3c as shown in FIG. 1c or sub-steps S3a-S3d as shown in FIG. 1d. In this manner, two or more layers 3 of photocurable resin 1 are spin coated and the layers 3 are arranged on top of each other on the spinnable substrate 2, and each layer 3 may comprise two or more sub-layers 3a.

FIGS. 2a-2d shows illustrative examples of polymer-based structures 5 that are made using methods and systems according to embodiments of the present invention. The figures are only used for illustrative purposes and does not necessarily show realistic examples of 3D-printed polymer-based structures 5.

FIG. 2a shows a polymer-based structure 5 comprising a single polymer-based substructure 6 which is 3D-printed using a single layer 3 of photocurable resin 1 on the spinnable substrate 2. This polymer-based structure 5 thus represents a result of a single-layered 3D-printing method according to an embodiment of the present invention.

FIG. 2b shows a polymer-based structure 5, which like the polymer-based structure 5 shown in FIG. 2a is 3D-printed using a single layer 3. However, this polymer-based structure 5 comprises two polymer-based substructures 6, each of which is arranged in a sub-layer 3a of the layer 3 comprising the photocurable resin 1. This polymer-based structure 5 thus represents a result of a multi-layered 3D-printing method according to an embodiment of the present invention in which the multi-layer printing occurs within a single spin coated layer 3. A two-photon laser is an example of a light source which is particularly suitable for the purpose of printing polymer-based substructures 6 in individual sub-layers 3a, as a key benefit of a two-photon laser it its ability to focus irradiation on a tiny focal volume.

FIG. 2c shows a polymer-based structure 5 comprising two polymer-based substructures 6. As opposed to the structure 5 shown in FIG. 2b, the substructures 6 shown in FIG. 2c are each contained within separate layers 3. Thus, a single layer 3 of photocurable resin 1 is used in the 3D-printing of a single layer, or polymer-based substructure 6, of the polymer-based structure 5. This polymer-based structure 5 thus represents a result of a multi-layered 3D-printing method according to an embodiment of the invention in which the multi-layered printing occurs by printing in individual spin coated layers 3.

FIG. 2d shows a polymer-based structure 5 comprising four polymer-based substructures 6. The two uppermost polymer-based substructures 6 are contained within the uppermost spin coated layer 3 and the two lowermost polymer-based substructures 6 are contained within the lowermost spin coated layer 3. This polymer-based structure 5 thus represents a result of a multi-layered 3D-printing method according to an embodiment of the invention in which the multi-layered printing occurs by a combination of spin coating two layers 3 and 3D-printing in two sub-layers 3a of each layer 3.

From the above description relating to FIGS. 1a-1d and 2a-2d a skilled reader will appreciate that a polymer-based structure 5 can be made using one or more spin coated layers 3 of photocurable resin, and the 3D-printing within a layer 3 can be performed in the entire height of the layer 3, or it can be performed in individual sublayers 3a of a spin coated layer 3. By these two approaches, or by a combination of these two approaches it becomes possible to 3D-print a polymer-based structure 5 comprising one or more polymer-based substructures 6, the substructures 6 constituting individual layers of the polymer-based structure 5.

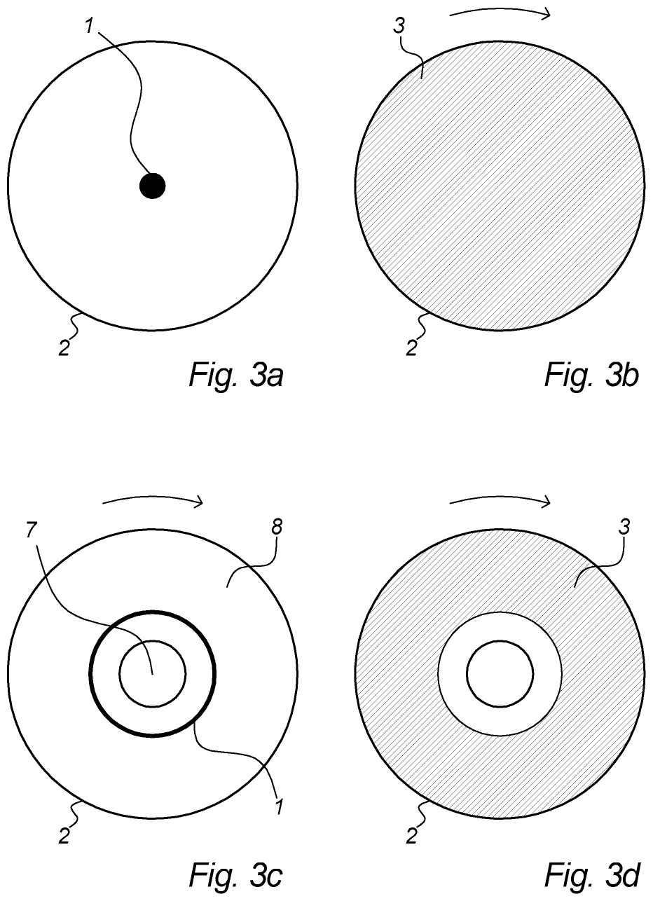

FIG. 3a shows a step of depositing a photocurable resin 1 onto a spinnable substrate 2 according to an embodiment of the invention. In this embodiment of the invention, the spinnable substrate 2 is a disc-shaped spinnable substrate 2, however, according to other embodiments of the invention the spinnable substrate 2 may take any other shape.

FIG. 3b shows a step of spin coating a layer 3 comprising the photocurable resin 1 as deposited on the spinnable substrate 2 in the embodiment of FIG. 3a. By spinning the spinnable substrate 2 in a spinning direction (illustrated by the arrow in FIG. 3b) the photocurable resin 1 is subjected to centrifugal forces which spreads the photocurable resin away from the center of rotation and a uniform layer 3 comprising the photocurable resin 1 is formed on the spinnable substrate 2.

FIG. 3c shows an alternative embodiment in which the spinnable substrate 2 is a disc-shaped spinnable substrate 2 comprising a center portion 7 and a peripheral portion 8 disposed around the center portion 7. The spinnable substrate 2 has a shape which resembles that of a data disc such as a CD-ROM, DVD, HD-DVD or a Blu-Ray disc. In an embodiment of the invention, the spinnable substrate 2 comprises such a data disc. In yet another embodiment of the invention, the spinnable substrate consist of such a data disc. The center portion 7 represents a portion of the spinnable substrate 2 which is used for attaching and fixating the spinnable substrate 2 to a driving system for spinning the spinnable substrate. In embodiments of the invention where the spinnable substrate resembles the shape of a data disc, such as a CD-ROM, DVD, HD-DVD or Blu-Ray disc, or includes such a data disc, the center portion 7 is a through-hole. Consequently, the center portion 7 represents a portion of the spinnable substrate 2 which is not usable for depositing a photocurable resin 1 and spin coating a layer 3 comprising the photocurable resin. Therefore, the photocurable resin 1 is deposited onto the peripheral portion 8 of the spinnable substrate 2. In this embodiment of the invention, the photocurable resin has been deposited from a fixed position over the spinnable substrate 2 while the spinnable substrate has spun around at a first rotational speed of between 60 and 120 rpm (rotations per minute) in a spinning direction (illustrated by the arrow in FIG. 3c). The result of this is that a donut-shaped deposit of the photocurable resin 1 is formed on the spinnable substrate. The donut-shaped deposit of the photocurable resin 1 is thus disposed around the center portion 7.

FIG. 3d shows a step of spin coating a layer 3 comprising the photocurable resin 1 as deposited in a donut-shape on the spinnable substrate 2 in the embodiment of FIG. 3c. By spinning the spinnable substrate 2 in a spinning direction (illustrated by the arrow in FIG. 3d) the photocurable resin 1 is subjected to centrifugal forces which spreads the photocurable resin away from the donut-shaped deposit and a uniform layer 3 comprising the photocurable resin 1 is formed on the spinnable substrate 2 on the peripheral portion 8.

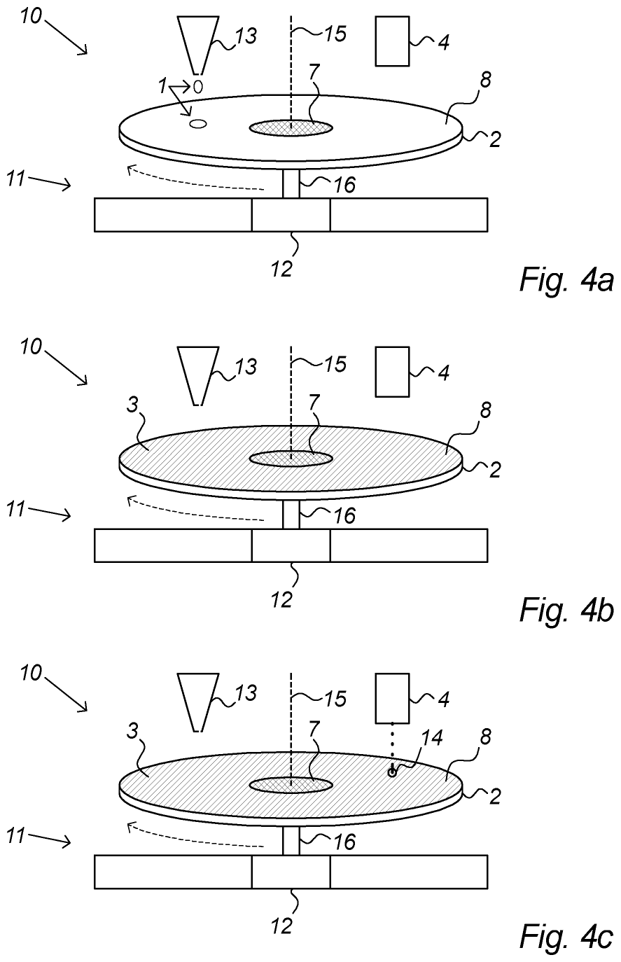

FIGS. 4a-4c shows a system 10 for 3D-printing a polymer-based structure 5 comprising at least one polymer-based substructure 6 according to an embodiment of the invention.

FIG. 4a shows a system 10 for 3D-printing a polymer-based structure 5 which comprises a driving system 11 for receiving and fixating a spinnable substrate 2 thereto. The driving system 11 comprises a motor 12 configured to spin the spinnable substrate 2 around an axis of rotation 15 whish passes through the plane in which the spinnable substrate 2 is positioned when it is not spinning around. In this embodiment of the invention, the driving system 11 comprises a spindle 16 which is used to transfer a rotational force from the motor 12 to the spinnable substrate 2. Furthermore, the spindle 16 is used as an attachment member for attaching the spinnable substrate 2 to the driving system 11. In other embodiments, the rotational force from the motor 12 may be transferred to the spinnable substrate 2 in other ways than a spindle 16 such as by use of gears or belts.

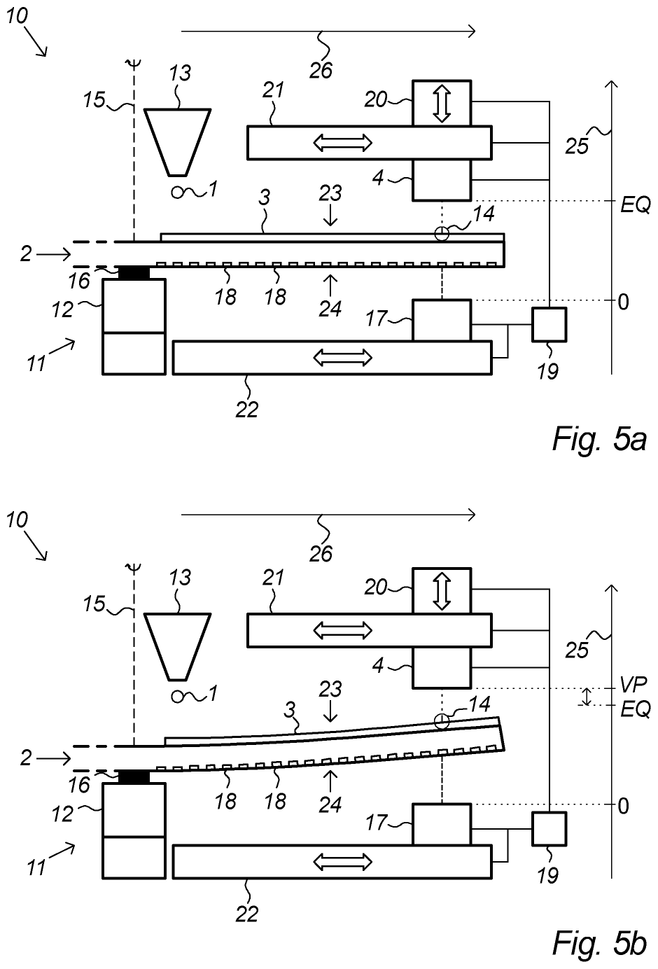

FIGS. 5a-5b illustrate side-views of a cross-section of a system 10 for 3D-printing a polymer-based structure 5 comprising at least one polymer-based substructure 6 according to an embodiment of the invention.

As seen in FIG. 5a the system 10 comprises a driving system 11 comprising a motor 12 and a spindle 16. A spinnable substrate 2 is attached and fixated to the driving system 11, such that the motor 12 may rotate/spin the spinnable substrate 2 around an axis of rotation 15. The system 10 further comprises a dispenser 13 for dispensing a photocurable resin 1 onto the spinnable substrate 2 such that a layer 3 comprising the photocurable resin 1 is spin coated on top of the spinnable substrate 2. In this embodiment of the invention, the spinnable substrate 2 is a disc-shaped spinnable substrate 2 in the form of a data disc, such as a Blu-Ray disc comprising data tracks 18 at a second side 24 of the spinnable substrate/disc. The layer 3 comprising the photocurable resin 1 is located on an opposite first side 23 of the spinnable substrate 2.

As seen in FIG. 5a, the system 10 further comprises a light source 4 which in this embodiment of the invention comprises a laser which emits light at a center wavelength (wavelength of greatest light intensity) of 405 nanometres. Such a light source may also typically be found in an optical pickup unit of a Blu-Ray drive. As seen, the light source 4 is configured to irradiate the layer 3 at a selected position 14, and the power provided by the laser light is used to cure the photocurable resin 1 of the layer 3 at this position 14. In this example, the light source is arranged to provide a light power of 200 microwatts, however this power may be changed according to needs. For example, a higher power may be used to deposit the same amount of light energy in a shorter time interval. This may be relevant if the spinnable substrate 2 spins at a higher rotational speed. Likewise, the power may be reduced such that the same amount of light energy is transferred to the layer 3 over as longer time duration. This may be relevant if them spinnable substrate spins at a lower rotational speed.

The system 10 comprises a first radial displacement unit 21 which is configured to translate the light source 4 backwards and forwards along a radial axis 26 extending between the center of rotation of the spinnable substrate, i.e., from the axis of rotation 15, and an edge of the spinnable substrate 2, and parallel to the first side 23 of the spinnable substrate 2. By translation of the light source 4 along the radial axis 26, it is possible for the 3D-printing system 10 to irradiate selected portions 14 having various radial coordinates on the spin coated layer 3. In this embodiment of the invention, the first radial displacement unit 21 comprises a sled motor. The system 10 further comprises a vertical displacement unit 20 configured to translate the light source 4 upwards and downwards along a vertical axis 25 which is parallel to the axis of rotation 15. In this embodiment of the invention, the vertical displacement unit comprises a piezo motor, however, in other embodiments of the invention, the vertical displacement unit comprises other means of vertically translating the light source 4, such as a stepper motor. In this way, the system 10 is able to irradiate various selected positions 14 in the layer 3 along the vertical axis 14, or to irradiate various selected positions 14 in a plurality of layers 3 disposed on top of each other (FIG. 5a only shows a single layer 3 comprising a photocurable resin 1, however, the system 10 is able to also irradiate selected positions 14 in a plurality of layers 3 although not shown in the figure). In this figure it is seen that the light source 4 is positioned in an equilibrium position EQ along the vertical axis 25. The equilibrium position represents a position of the light source 4 when the spinnable substrate 2 is in a stable state, i.e., the spinnable substrate is not deflected away from its natural resting position when it is stationary/not spinning. Naturally, the equilibrium position EQ depends on the position within the layer 3, or within a plurality of layers (not shown in the figure), where light energy from the light source 4 is to be deposited.

The system 10 further comprises a detection unit 17 which is arranged to detect a vertical position of the second side 24 of the spinnable substrate 2 along the vertical axis 25. In this embodiment of the invention, the detection unit 17 comprises an optical pickup unit having a similar light source as the light source 4. The detection unit 17 may further be translated along the radial axis 26 in a similar way to the light source 4. In this case, the detection unit 17 is translated by means of a second radial displacement unit 22. In this embodiment of the invention, the second radial displacement unit 22 comprises a sled motor.

A skilled reader will appreciate the way that the system 10 resembles that of a data drive, such as a CD-ROM drive, a DVD drive, an HD-DVD drive or a Blu-Ray Drive. In another embodiment of the invention, the parts of the system 10 below the spinnable substrate 2 at the second side 24 of the spinnable substrate comprises components of such a data drive.

As seen, the detection unit 17 is in a communicative connection, such as in a cabled connection, with a controller 19, which in turn is also in communicative connection, such as in a cabled connection, with the vertical displacement unit 20. The detection unit 17 is configured to detect a vertical position of the spinnable substrate 2 along the vertical axis 25, and based on such a detection, to provide the controller with a signal representing this vertical position. In response to receiving the signal from the detection unit 17, the controller 19 may provide a signal to the vertical displacement unit 20. In this embodiment of the invention, the signal from the controller 19 to the vertical displacement unit 20 is an inverted signal from the signal provided by the detection unit for the controller 19. In this manner, the detection unit 17, controller 19, and vertical displacement unit 20 may, in combination, be configured to compensate vertical displacement of the spinnable substrate 2, i.e., wobbling of the disc-shaped spinnable substrate 2.

FIG. 5b shows the same system 10 as shown in FIG. 5a. However, FIG. 5b shows a situation where the disc-shaped spinnable substrate 2 is deflected vertically along the vertical axis 25. The skilled reader will appreciate that this figure only shows an instant of the rotation/spinning of the spinnable substrate 2 and does therefore not illustrate the dynamics of disc wobbling. In practice, the deflection of the spinnable substrate 2 may alternate between a bended-up deflection as shown in FIG. 5a and a bended-down deflection (not shown), where the deflection of the spinnable substrate 2 is in an opposite direction along the vertical axis 25.

As the spinnable substrate 2 wobbles or deflects along the vertical axis 25 when it is spinning around, the wobbling is compensated by the system 10. In FIG. 5b is shown how the vertical position (VP) of the light source 4 is adjusted away to a new position along the vertical axis 25, away from the equilibrium position EQ, to compensate for the upward deflection of the spinnable substrate 2. In this manner, the system 10 can maintain the same distance between the light source 4 and the layer 3 as the distance between the two as shown in FIG. 5a. In a similar way, the system 10 is also able to compensate for a downward deflection by vertically translating the light source in an opposite direction along the vertical axis 25.

As the system can translate the light source 4 along the radial axis 26, while also translating the detection unit 17 an equal amount in the same direction of translation along the radial axis 26, the system 10 is able to compensate for disc wobbling regardless of where the light source 4 is positioned with respect to the spinnable substrate 2.

The data tracks 18 shown on FIGS. 5a and 5b are used as basis for control of the irradiation of the layer 3 comprising the photocurable resin 1. The detection unit 17 is arranged to read the data tracks, similar to how a data drive reads data on a data disc, and these readings may be used to determine over what position on the spinnable substrate 2 the light source 4 is positioned. On the basis of such readings, the light source 4 may be triggered to emit light at desired points in time, and for desired durations, such that the desired polymer-based structures 5 comprising one or more polymer-based substructures 6 are printed.

As also seen in FIGS. 5a and 5b, the light source 4, the first radial displacement unit 21, and the second radial displacement 22 are in communicative connection, such as a cabled connection, with the controller 19. In this way control signals may be provided from the controller 19 to these components. In other embodiments of the invention, the system 10 may comprise any number of additional controllers. In such cases, the above-described compensation may be controlled by the controller 19 and other control signals, such as control signals for the light source 4, the first radial displacement unit 21 and the second radial displacement unit may be provided by one or more auxiliary controllers (not shown in figures).

The system 10 as shown in FIGS. 5a and 5b are arranged to carry out any steps of the methods as described in relation to FIGS. 1a-1d and FIGS. 3a-3d.

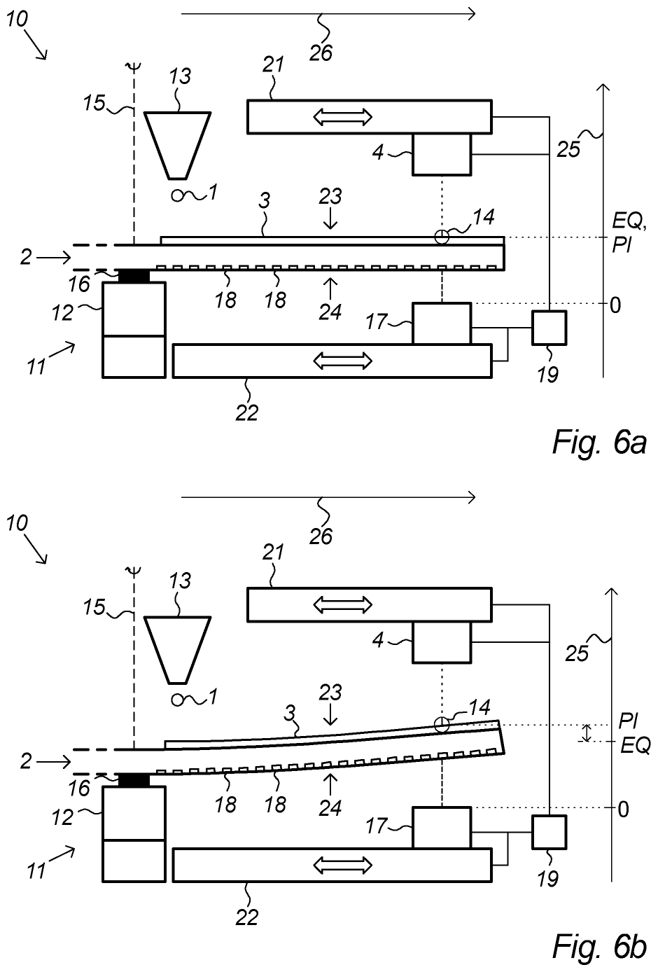

The system 10 as shown in FIGS. 5a and 5b is one embodiment showing how to dynamically adjust a point of interaction of light of the light source with the spinnable substrate. FIGS. 6a-6b illustrates another embodiment showing how to dynamically adjust a point of interaction of light of the light source and the spinnable substrate.

The system 10 as shown in FIG. 6a resembles that shown in FIG. 5a with the distinction that instead of the system dynamically adjusting a position of the light source 4, the system 10 of FIG. 6a is configured to dynamically adjusting the lighting produced by the light source 4. In this embodiment, this dynamic adjustment is performed by adjusting a vertical position of focus of the light source 4 through, e.g., adjustment of light optics. FIG. 6a shows a situation where the spinnable substrate 2 is either stationary, or at an instance of rotation where the vertical position, along vertical axis 25, of a point of interaction of light (PI) with the spinnable substrate is coincident with an equilibrium position EQ along the vertical axis 25. The Equilibrium position EQ serves to demonstrate a point of reference that is usable for understanding dynamics of the system 10 demonstrated in FIG. 6b.

FIG. 6b illustrates another instance of rotation of the spinnable substrate during a step of irradiation. As seen, the spinnable substrate 2, in the shape of a disc, has deflected upwards towards the light source 4 due to disc wobble. In order to compensate for this disc wobble, the point of interaction (PI) is adjusted upwards away from the equilibrium position (EQ) along the vertical axis 25. As seen, from FIGS. 6a and 6b the projection of the selected position 14 onto the vertical axis 25 may be regarded as the point of interaction PI. In this way, the system 10 is capable of dynamically adjusting the light to compensate for the wobbling of the spinnable substrate.

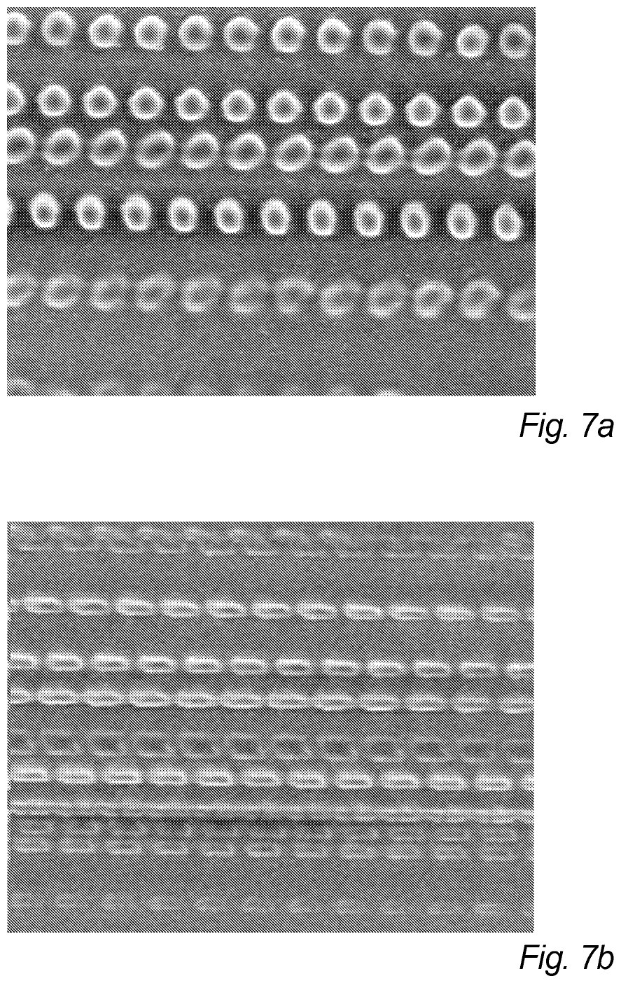

FIG. 7a-7b shows images of actual polymer-based structures obtained by methods and systems according to embodiments of the present invention. The images are obtained by SEM (Scanning Electron Microscopy). The linear printing speed was above 1000 mm per second.

FIG. 7a shows printed feature with a characteristic size of 17.6 micrometer when measured along a horizontal axis on FIG. 7a. FIG. 7b shows printed feature with a characteristic size of 5.97 micrometer when measured along a horizontal axis on FIG. 67. FIG. 7a-7b illustrate how differently shaped and sized features are printed, using a shorter laser exposure time on FIG. 7b than on FIG. 7a to achieve smaller features.

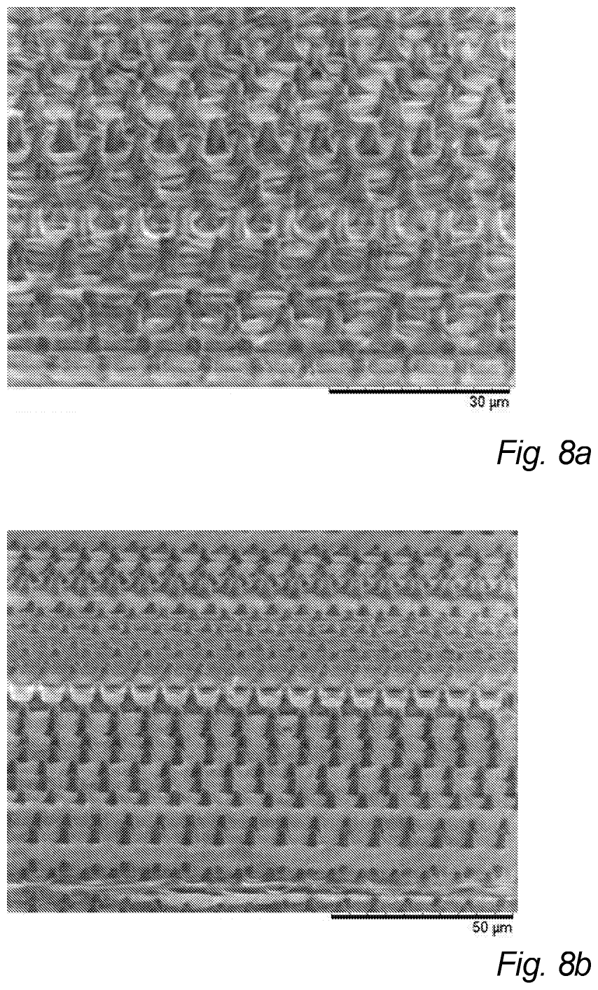

FIG. 8a-8b shows images of actual polymer-based structures obtained by methods and systems according to embodiments of the present invention. The images are obtained by SEM (Scanning Electron Microscopy).

The samples shown on FIG. 8a-8b are made by printing smaller structures on top of larger ones, i.e. an example of printing layers on top of layers.

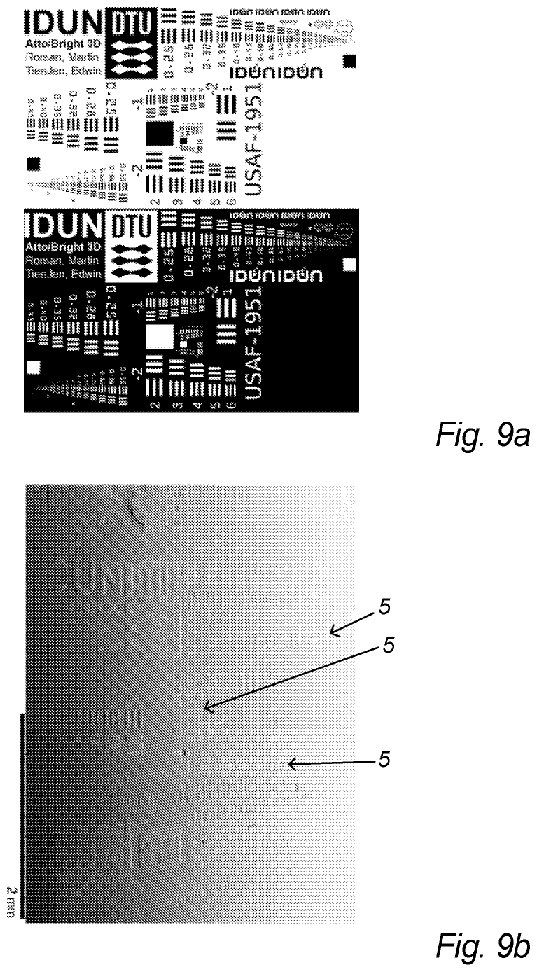

FIGS. 9a-9b serves to illustrate the accuracy and predictability with which polymer-based structures 5 may be 3D-printed according to methods of the present invention. FIG. 9a shows, among others, a 1951 USAF resolution test chart. The test chart is widely used in optical engineering laboratory work to analyze and validate imaging systems such as microscopes (including scanning electron microscopes), cameras, and image scanners. For the purpose of the present invention, the test chart is used to illustrate an example of the precision of 3D-printing achieved by methods and systems according to embodiments of the present invention. For this purpose, the test chart is particularly suitable as it comprises objects of various sizes, geometries, and orientations.

FIG. 9b shows an actual SEM-image of a resulting 3D-print of the test chart using a method and a system according to embodiments of the invention. The image has been obtained by use of SEM. The 3D-printed polymer-based structures 5 shown in the image have been produced by depositing photocurable resin, specifically a HTM140V2 polymer from EnvisionTEC (dynamic viscosity of 150 cP), onto a disc-shaped spinnable substrate while spinning the spinnable substrate at a deposition rotational speed of 60 rpm. The spinnable substrate was subsequently spun at a spin-coating rotational speed of 400 rpm for 10 seconds to form a spin-coated layer. After the step of producing a spin-coated layer, the spinnable substrate was spun at a print rotational speed of 200 rpm (which resulted in a linear printing speed of 860 mm/s), during the last step of irradiating the spin-coated layer with light from a light source. The light source was a semiconductor laser having a laser power of 0.5 mW.

The 3D-printed polymer-based structures 5 clearly resembles the test chart shown in FIG. 9a. This clearly demonstrates the accuracy and predictability of 3D-printing achieved by the methods and systems of the present invention.

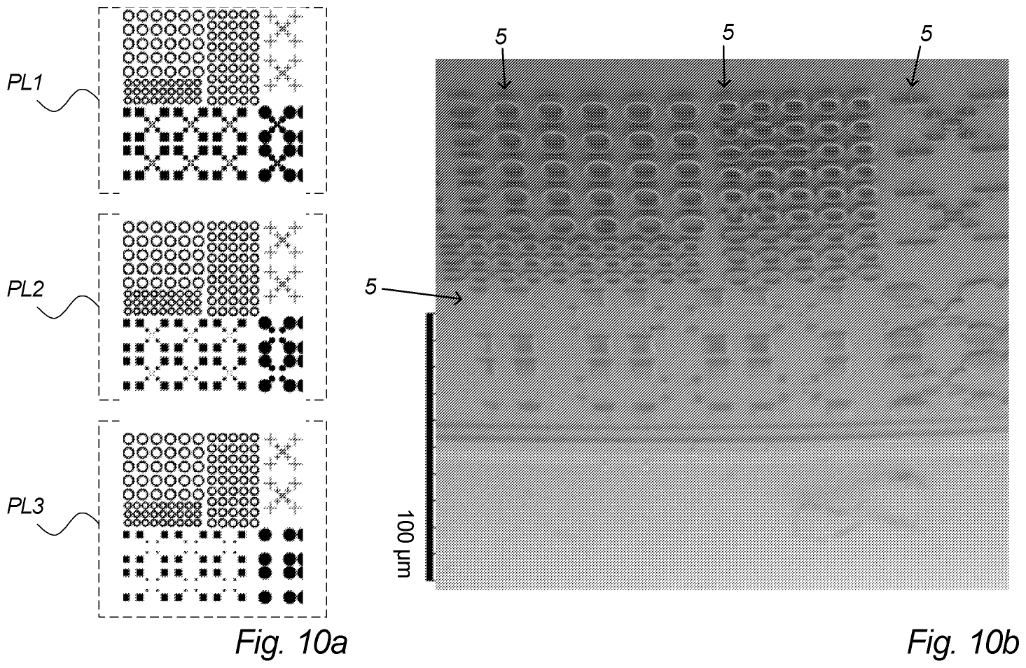

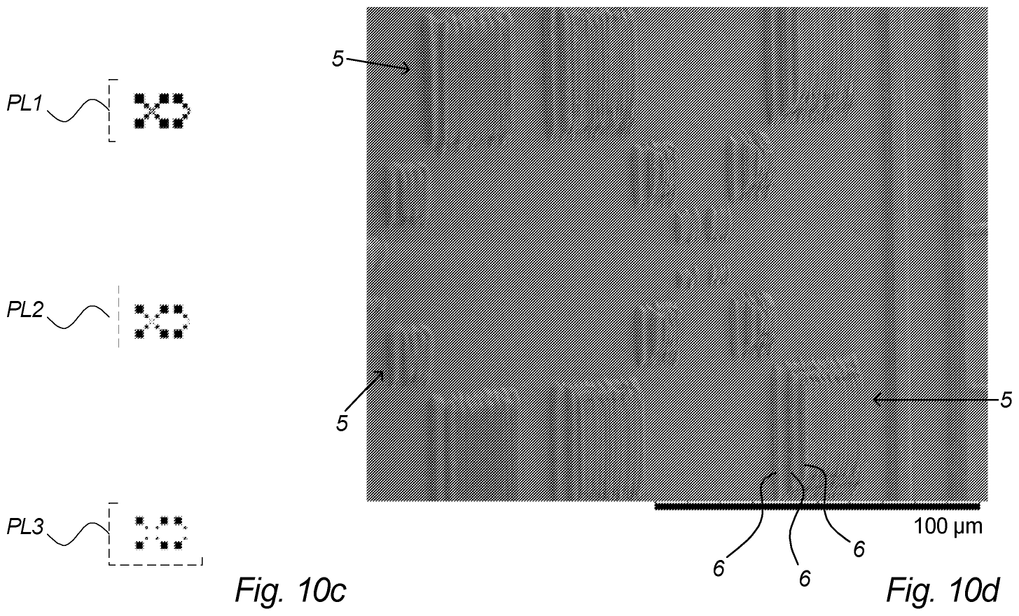

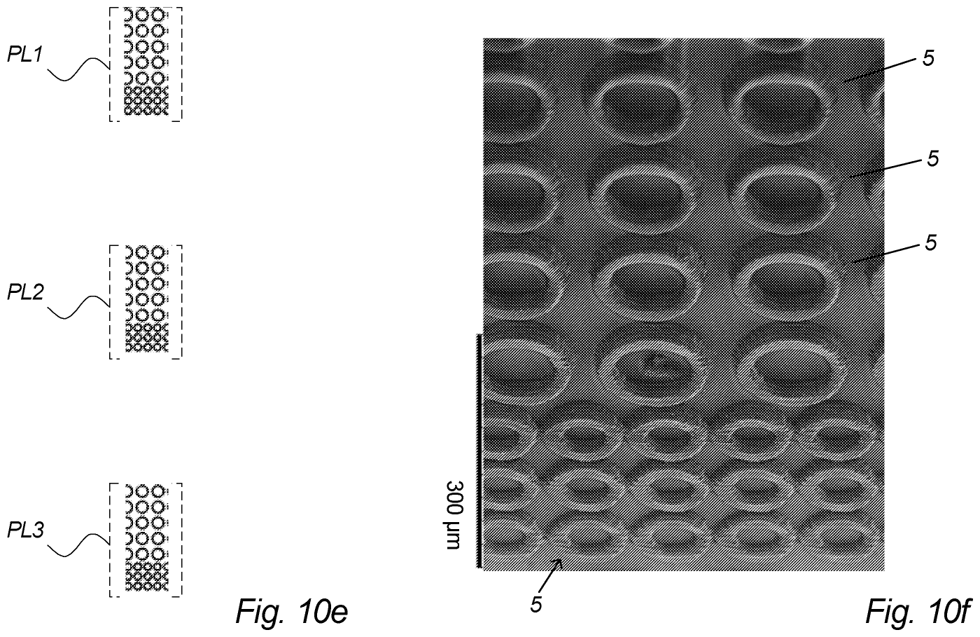

FIGS. 10a-10g also serve to illustrate the accuracy and predictability with which polymer-based structures 5 may be 3D-printed.

FIG. 10a illustrates three pictorial representations PL1-PL3 of polymer-based structures to be printed according to a method of the present invention. The first pictorial representation PL1 represents a first layer of polymer-based structures to be 3D-printed, the second pictorial representation PL2 represents a subsequent second layer of the polymer-based structures to be 3D printed, and the third pictorial representation PL3 represents a further subsequent layer of the polymer-based structures to be 3D-printed. The pictorial representations PL1-PL3 are suitable as input to a computer which is arranged to execute a method according to embodiments of the present invention.

FIG. 10b shows an image of actual polymer-based structures 5 printed according to a method according to an embodiment of the present invention. The image is obtained by a scanning electron microscope (SEM). The 3D-printed polymer-based structures 5 of FIG. 10b comprises three layers, with each layer being printed according to the respective pictorial representations PL1-PL3 shown in FIG. 10a. The 3D-printed polymer-based structures shown in the image have been produced by depositing photocurable resin, specifically a HTM140V2 polymer from EnvisionTEC (dynamic viscosity of 150 cP), onto a disc-shaped spinnable substrate while spinning the spinnable substrate at a deposition rotational speed of 60 rpm. The spinnable substrate was subsequently spun at a spin-coating rotational speed of 500 rpm to form a first spin-coated layer. After the step of producing a spin-coated layer, the spinnable substrate was spun at a print rotational speed of 200 rpm (which resulted in a linear printing speed of 860 mm/s), during the last step of irradiating the spin-coated layer with light from a light source. The light source was a semiconductor laser having a laser power of 0.5 mW. A second layer was 3D-printed by depositing photocurable resin (also HTM140V2 polymer from Envision TEC) at a deposition rotational speed of 60 rpm, spin coating a layer by spinning the spinnable substrate at a spin-coating rotational speed of 400 rpm to form a second spin-coated layer on top of the previously formed first layer. The printing of the second layer occurred in the same way as for the first layer. A third layer was 3D-printed by depositing photocurable resin (also HTM140V2 polymer from Envision TEC) at a deposition rotational speed of 60 rpm, spin coating a layer by spinning the spinnable substrate at a spin-coating rotational speed of 300 rpm to form a third spin-coated layer on top of the previously formed second layer. The printing of the third layer occurred in the same way as for the first and second layer. In this sense, each polymer-based structure 5 comprises three polymer-based substructures 6 (which may be difficult to discern from the SEM-image —see FIG. 10g in this regard), each polymer-based substructure 6 being 3D-printed in an individual layer of the polymer-based structure 5.

FIG. 10c illustrates pictorial representations PL1-PL3. These pictorial representations correspond to a part of the pictorial representations shown in FIG. 10a.

FIG. 10d shows an image of actual polymer-based structures 5 printed according to a method according to an embodiment of the present invention. The image is obtained by a scanning electron microscope (SEM). The image shows a part of the image in FIG. 10b, albeit at a different view angle and at a different zoom level. Thus, the polymer-based structures 5 seen in FIG. 10d has been made according to the procedure mentioned in relation to FIG. 10b. As seen, the polymer-based structures on FIG. 10d match the corresponding pictorial representations PL1-PL3 on FIG. 10c on a layer-by-layer basis. That is, each polymer-based structure 5 comprises three polymer-based substructures 6 that are printed in individual 3D-printed layers.

FIG. 10e illustrates pictorial representations PL1-PL3. These pictorial representations correspond to a part of the pictorial representations shown in FIG. 10a.

FIG. 10f shows an image of actual polymer-based structures 5 printed according to a method according to an embodiment of the present invention. The image is obtained by a scanning electron microscope (SEM). The image shows a part of the image in FIG. 10b, albeit at a different view angle and at a different zoom level. Thus, the polymer-based structures 5 seen in FIG. 10f has been made according to the procedure mentioned in relation to FIG. 10b. The polymer-based structures 5 on FIG. 10f match the corresponding pictorial representations PL1-PL3 on FIG. 10e on a layer-by-layer basis. Take note that each of the polymer-based structures 5 shown in FIG. 10f comprises three polymer-based substructures 6 printed in individual layers, which is more clearly seen in FIG. 10g.

FIG. 10g shows a zoom in on a polymer-based structure from FIG. 10b. As seen, the polymer-based structure 5 comprises three layers L1-L3 of polymer-based structure. Each of the printed layers L1-L3 of the polymer-based structure 5 comprises a polymer-based substructure 6. That is, the 3D-printed polymer-based structure 5 comprises three polymer-based substructures 6; one polymer-based substructure 6 per layer. The polymer-based substructure 6 have thus been printed from corresponding spin-coated layers 3 in the manner described with reference to FIG. 2c.

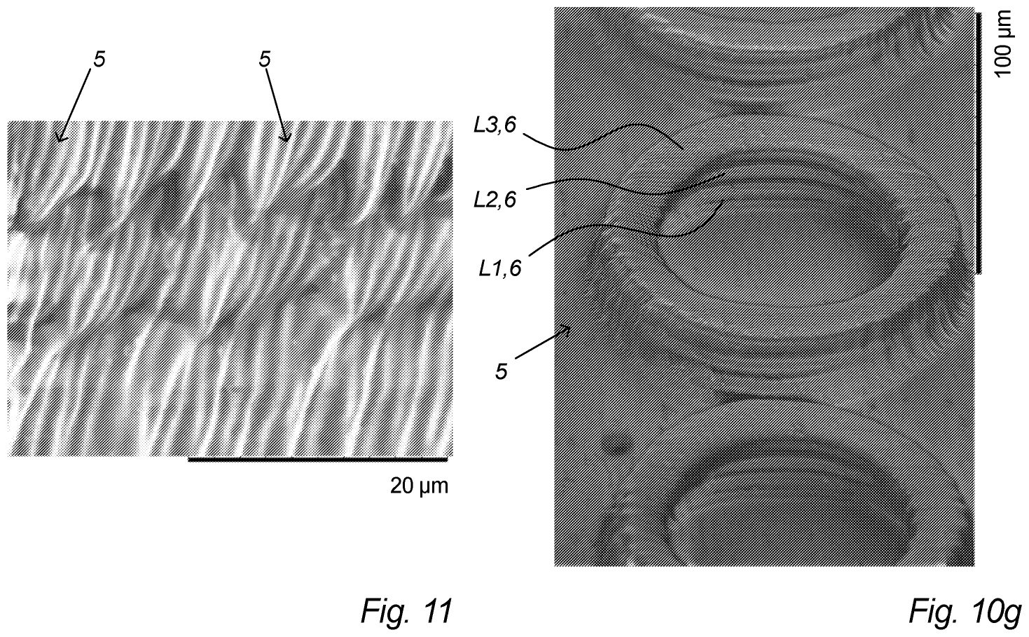

FIG. 11 illustrates an SEM image of another 3D-printed polymer-based structures 5 printed using a system and a method according to embodiments of the present invention.

### LIST OF REFERENCE SIGNS

1 Photocurable resin
2 Spinnable substrate
3 Spin-coated layer
3a Sublayer of spin-coated layer
4 Light source
5 Polymer-based structure
6 Polymer-based substructure
7 Center portion
8 Peripheral portion
10 System for 3D-printing
11 Driving system
12 Motor
13 Dispenser
14 Selected position
15 Axis of rotation
16 Spindle
17 Detection unit
18 Data track
19 Controller
20 Vertical displacement unit
21 First radial displacement unit
22 Second radial displacement unit
23 First side of spinnable substrate
24 Second side of spinnable substrate
25 Vertical axis
26 Radial axis
EQ Equilibrium position
PI Point of interaction
VP Vertical position
S1-S4 Method steps
S3a-S3d Method sub-steps
PL1-PL3 Pictorial representations of polymer-based structures
L1-L3 Layers of polymer-based structure

1. A method of 3D-printing a polymer-based structure comprising at least one polymer-based substructure, said method comprising the steps of:
(i) depositing a photocurable resin onto a spinnable substrate;
(ii) spin coating a layer comprising said photocurable resin on said spinnable substrate by spinning said spinnable substrate, wherein a thickness of said layer is adjustable through adjustment of a spin coating rotational speed of said spinnable substrate; and
(iii) irradiating said layer, while spinning said spinnable substrate, at one or more selected positions with a light source to cure at least a portion of said layer,
thereby forming a polymer-based substructure.

2. (canceled)

3. The method of 3D-printing a polymer-based structure according to claim 1, wherein said step of depositing comprises depositing said photocurable resin onto said spinnable substrate while spinning said spinnable substrate at a deposition rotational speed.

4. The method of 3D-printing a polymer-based structure according to claim 1, wherein said step of depositing comprises depositing said photocurable resin in a predetermined amount.

5. The method of 3D-printing a polymer-based structure according to claim 1, wherein said spinnable substrate is a disc-shaped spinnable substrate wherein a diameter of said disc-shaped spinnable substrate is in the range from 5 mm to 300 mm.

6. (canceled)

7. (canceled)

8. (canceled)

9. (canceled)

10. The method of 3D-printing a polymer-based structure according to claim 1, wherein said step of irradiating said layer, while spinning said spinnable substrate, comprises dynamically adjusting a point of interaction of light of said light source with said spinnable substrate.

11. The method of 3D-printing a polymer-based structure according to claim 10, wherein said dynamically adjusting comprises detecting movements of said spinnable substrate along an axis perpendicular to a plane in which said spinnable substrate is positioned and adjusting a point of interaction of light of said light source with said spinnable substrate.

12. The method of 3D-printing a polymer-based structure according to claim 1, wherein said step of irradiating said layer, while spinning said spinnable substrate, comprises dynamically adjusting a position of said light source with respect to an equilibrium position.

13. The method of 3D-printing a polymer-based structure according to claim 12, wherein said dynamically adjusting comprises detecting movements of said spinnable substrate along an axis perpendicular to a plane in which said spinnable substrate is positioned and adjusting said position of said light source along said axis on the basis of said detected movements.

14. (canceled)

15. (canceled)

16. The method of 3D-printing a polymer-based structure according to claim 1, wherein said step of irradiating said layer comprises sequentially turning on and off said light source.

17. The method of 3D-printing a polymer-based structure according to claim 12, wherein said step of spin coating comprises spinning said spinnable substrate at a spin coating rotational speed and said step of irradiating said layer comprises spinning said spinnable substrate at a print rotational speed, wherein said spin coating rotational speed is equal to or greater than said print rotational speed.

18. (canceled)

19. The method of 3D-printing a polymer-based structure according to claim 12, wherein said light source is a first light source and wherein said step of irradiating comprises irradiating at one or more selected positions with one or more further light sources including at least a second light source.

20. The method of 3D-printing a polymer-based structure according to claim 1, wherein said polymer-based structure comprises a plurality of polymer-based substructures, and wherein said plurality of polymer-based substructures are produced by repeating step (iii) one or more further times.

21. The method of 3D-printing a polymer-based structure according to claim 1, wherein said method comprises a further step (iv) of repeating said steps (i)-(iii) one or more further times, thereby forming one or more further polymer-based substructures.

22. The method of 3D-printing a polymer-based structure according to claim 21, wherein for each repetition of said steps (i)-(iii), a spin coating rotational speed is reduced.

23. A system for 3D-printing a polymer-based structure comprising at least one polymer-based substructure, said system comprising:
a dispenser configured to deposit a photocurable resin onto a spinnable substrate; and
a driving system for receiving said spinnable substrate thereto, said driving system comprising a motor configured to spin said spinnable substrate to at least form a layer comprising said photocurable resin, wherein a thickness of said laver is adjustable through adjustment of a spin coating rotational speed of said spinnable substrate;
a controller; and
a light source configured to irradiate and cure said photocurable resin deposited onto said spinnable substrate, wherein said light source is configured to emit light in response to a control signal provided by said controller, and wherein said system is configured to dynamically adjust a point of interaction of said light source with said spinnable substrate.

24. The system for 3D-printing a polymer-based structure according to claim 23, wherein said system is configured to dynamically adjust said point of interaction of said light source with aid spinnable substrate by maintaining a relative distance between said light source and said spinnable substrate.

25. The system for 3D-printing a polymer-based structure according to claim 23, wherein said light source comprises a laser.

26. (canceled)

27. The system for 3D-printing a polymer-based structure according to according to claim 23, wherein said light source is arranged adjacent to a first side of said spinnable substrate, and wherein said system further comprises a detection unit arranged on a second side of said spinnable substrate, said first side and second side being opposite sides of said spinnable substrate, wherein said detection unit is arranged to detect movements of said spinnable substrate along an axis perpendicular to a plane in which said spinnable substrate is positioned.

28. (canceled)

29. The system for 3D-printing a polymer-based structure according to claim 23, wherein said spinnable substrate is a disc-shaped spinnable substrate.

30. The system for 3D-printing a polymer-based structure according to claim 23, wherein said light source is a first light source, and wherein said system comprises one or more further light sources including a second light source, said one or more further light sources being configured to irradiate and cure said photocurable resin deposited onto said spinnable substrate, wherein said one or more further light sources are configured to emit light in response to a control signal provided by said controller.

31. (canceled)
